(19) United States
(12) Patent Application Publication
(10) Pub. No.: US 2011/0180240 A1
(43) Pub. Date: Jul. 28, 2011

(54) CENTRIFUGAL BLOWER AND HEAT DISSIPATION DEVICE INCORPORATING THE SAME

(75) Inventors: XIN-XIANG ZHA, Shenzhen City (CN); JER-HAUR KUO, Tu-Cheng (TW)

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/753,129

(22) Filed: Apr. 2, 2010

(30) Foreign Application Priority Data
Jan. 23, 2010 (CN) 201010300626.6

(51) Int. Cl. H01L 23/467; F01D 1/02

(52) U.S. Cl. 165/121; 415/203

(57) ABSTRACT

A heat dissipation device includes a centrifugal blower and fins. The centrifugal blower includes a housing defining a space therein, and an impeller rotatably disposed in the space of the housing. The housing includes a bottom plate, an opposite top plate defining an air inlet therein, and a sidewall disposed between the bottom plate and the top plate. The sidewall defines an air outlet therein. The top plate further defines an opening therein between the air inlet and the air outlet. The opening is spaced from the air inlet via a partition rib. The impeller is located corresponding to the air inlet of the top plate, for driving air to enter the housing via the air inlet and the opening and to leave the housing via the air outlet. The fins are disposed on the bottom plate and located at the air outlet of the centrifugal blower.

### BACKGROUND

1. Technical Field

The disclosure generally relates to centrifugal blowers; and more particularly to a centrifugal blower which can provide a large amount of airflow, and a heat dissipation device incorporating the centrifugal blower.

2. Description of Related Art

It is well known that heat is produced by electronic components, such as integrated circuit chips, during normal operation. If such heat is not quickly removed, these electronic components may overheat. Therefore, heat dissipation devices are often used to cool these electronic components.

As an example, a heat dissipation device in the related art generally includes a fin assembly having a plurality of fins, and a centrifugal blower for creating an airflow through the fin assembly. The fin assembly is thermally connected to a heat generating electronic component such as a central processing unit (CPU) or a graphic processing unit (GPU) of a computer. Heat generated by the heat generating electronic component is transferred to the fins of the fin assembly, and then dissipated to the ambient atmosphere via the airflow flowing through the fin assembly.

Increasing the amount of airflow provided by the centrifugal blower is an effective way to improve the heat dissipation efficiency of the heat dissipation device. Conventional ways of satisfying such requirement are to change the configurations of blades of the centrifugal blower and change the parameters of the motor of the centrifugal blower. However, such changes complicate the design and the manufacture of the centrifugal blower and further increase the cost thereof.

What is needed, therefore, is a centrifugal blower capable of providing a large amount of airflow and having a simple structure and a low manufacturing cost.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a top plan view of a centrifugal blower of the related art.

FIG. 2 is an assembled, isometric view of a heat dissipation device in accordance with an exemplary embodiment of the present disclosure.

FIG. 3 is an exploded view of the heat dissipation device of FIG. 2.

FIG. 4 is similar to FIG. 3, but showing the heat dissipation device inverted.

FIG. 5 is a top plan view of the heat dissipation device of FIG. 2.

### DETAILED DESCRIPTION

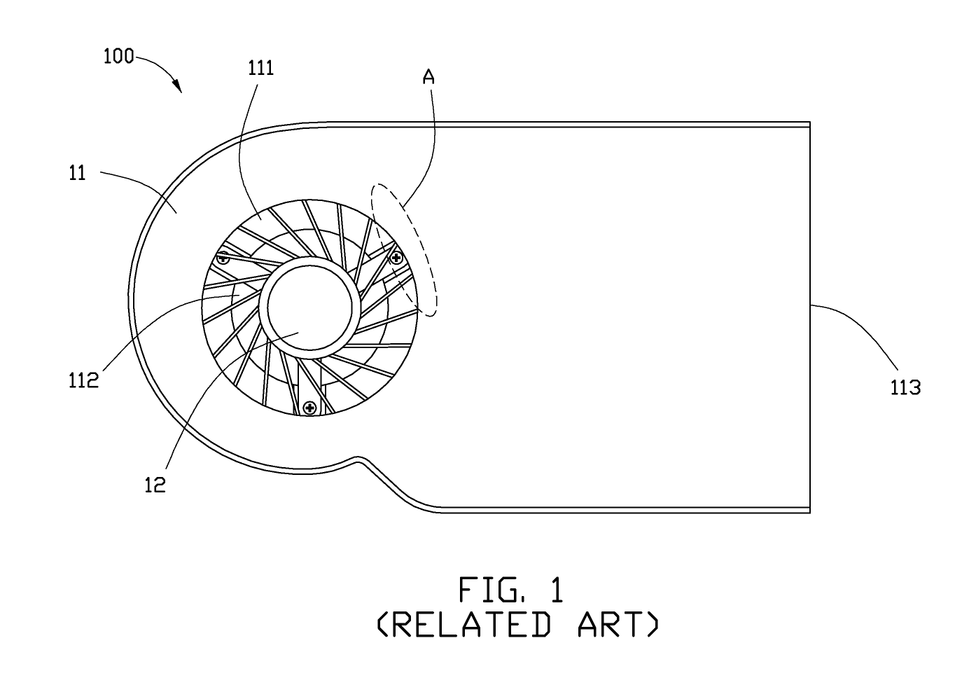

Referring to FIG. 1, a centrifugal blower 100 of the related art is shown. The centrifugal blower 100 includes a casing 11, and an impeller 12 rotatably disposed in an inner space of the casing 11. The casing 11 defines a top air inlet 111 in a top plate thereof, a bottom air inlet 112 in a bottom plate thereof, and an air outlet 113 in a sidewall thereof. In operation, the impeller 12 drives exterior air to enter the casing 11 via the top and bottom air inlets 111, 112, and then leave the casing 11 via the air outlet 113.

When the flow field of the airflow produced by the centrifugal blower was simulated by using computational fluid dynamics (CFD) software, it was found that a marked air-sucking phenomenon occurs at a region indicated by the closed broken line A. In other words, a sucking force at region A is stronger than at other regions of the top air inlet 111. Therefore, enlarging the area of the top air inlet 111 at region A to increase the amount of the air entering into the centrifugal blower 100 is at least desirable if not feasible. This is the guiding concept of the present invention.

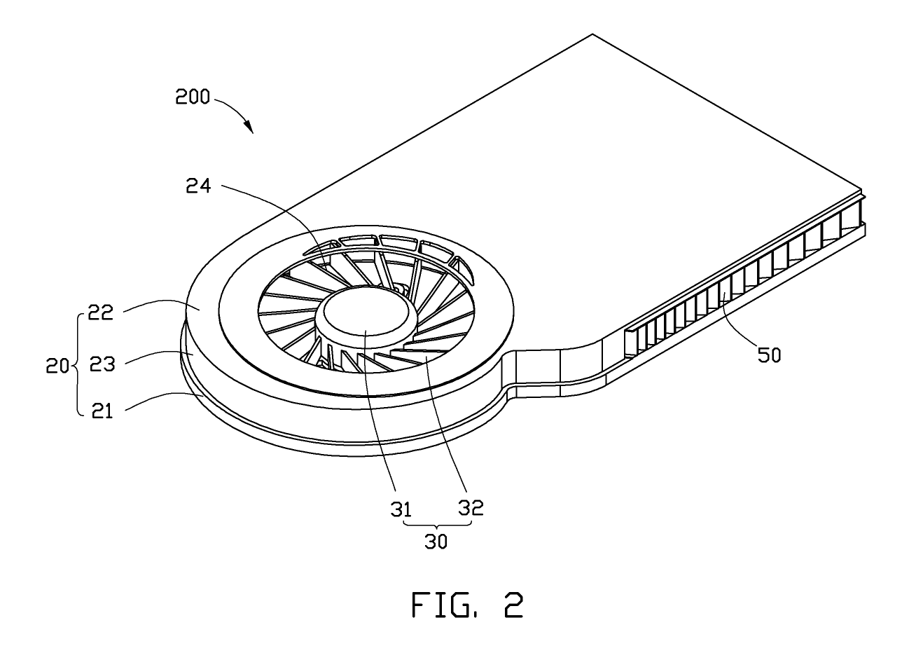

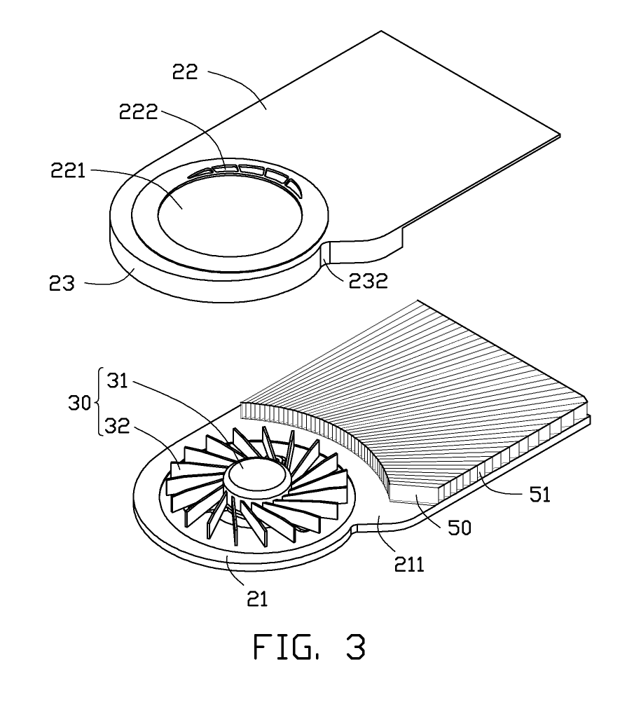

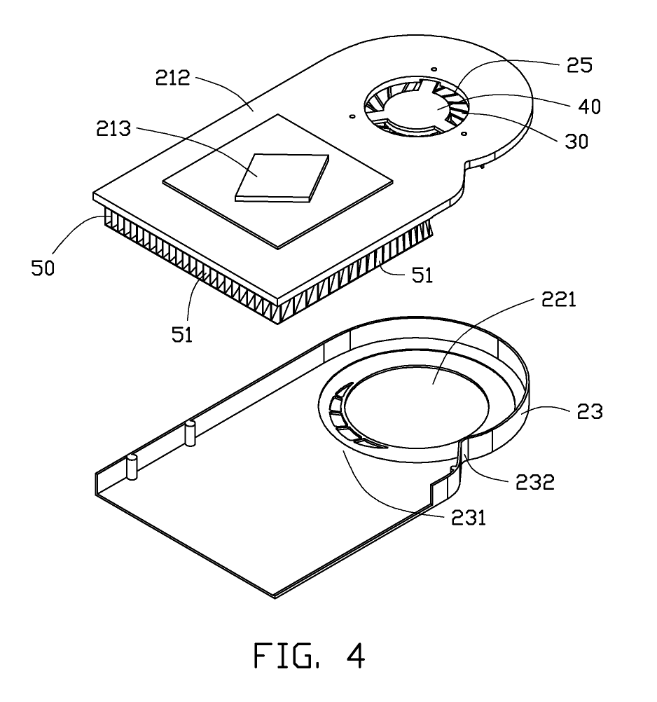

Referring to FIGS. 2-4, a heat dissipation device according to an exemplary embodiment of the present disclosure includes a centrifugal blower 200 and a plurality of fins 50. The centrifugal blower 200 includes a housing 20, and an impeller 30 rotatably disposed in the housing 20.

The housing 20 includes a bottom plate 21, an opposite top plate 22, and a sidewall 23 interconnecting the bottom plate 21 and the top plate 22. The bottom plate 21, the top plate 22 and the sidewall 23 cooperatively define a space 24 therebetween for receiving the impeller 30. The top plate 22 and the bottom plate 21 respectively define a first air inlet 221 and a second air inlet 25 therein. Exterior air enters the space 24 of the centrifugal blower 200 via the first and second air inlets 221, 25. The first and the second air inlets 221, 25 are both round-shaped in profile. The first air inlet 221 is concentric with the second air inlet 25, and has a diameter larger than that of the second air inlet 25.

A bracket 40 is disposed in the second air inlet 25 and mounted to the bottom plate 21. The impeller 30 is arranged in the space 24, and is located corresponding to the first air inlet 221 and the second air inlet 25. The impeller 30 includes a hub 31, and a plurality of blades 32 extending radially and outwardly from the hub 31. The hub 31 is concentric with the first air inlet 221 and the second air inlet 25. In other words, the center of the first air inlet 221 and the center of the second air inlet 25 are both located on a rotation axis of the impeller 30.

The bottom plate 21 is made of metal having a high thermal conductivity, such as copper or aluminum. The bottom plate 21 has an inner surface 211 facing the top plate 22, and an outer surface 212. The fins 20 are disposed on the inner surface 211 of the bottom plate 21, and are located at a side of the impeller 30. A plurality of air passages 51 are formed between adjacent fins 50. The bottom plate 21 thermally contacts the fins 50 for transferring heat to the fins 50. The top plate 22 extends outwardly to cover the fins 50. The bottom plate 21 has a heat absorbing block 213 formed on the outer surface 212 thereof, corresponding to the fins 50. The heat absorbing block 213 is used for thermally contacting a heat generating electronic component directly, or via a heat conducting member such as a heat pipe. Heat generated by the heat generating electronic component is transferred to the heat absorbing block 213 and then to the fins 50 through the bottom plate 21.

The sidewall 23 defines an air outlet 231 at a position corresponding to the fins 50, thereby allowing airflow created by the centrifugal blower 200 to flow into the air passages 51 between the fins 50. The sidewall 23 has a tongue 232 formed thereon at one side of the air outlet 231. In this embodiment, the sidewall 23 is integrally formed with the top plate 22 as a monolithic piece. In other embodiments, the sidewall 23 can be integrally formed with the bottom plate 21 as a monolithic piece.

The top plate 22 further defines an elongated opening 222 therein between the first air inlet 221 and the air outlet 231. The opening 222 is located adjacent to the other side of the air outlet 231 farthest from the tongue 232. The opening 222 is spaced from the first air inlet 221 by an arc-shaped partition rib 223. The opening 222 is crescent-shaped and extends along a periphery of the first air inlet 221. The top plate 22 forms a plurality of connecting ribs 224 in the opening 222. The connecting ribs 224 are arranged along a direction of extension of the crescent shape of the opening 222, and are spaced from each other. The opening 222 is divided into a plurality of small-sized apertures (not labeled) by the connecting ribs 224. A distance between two adjacent connecting ribs 224, i.e., a length of each aperture, is substantially equal to a distance between two adjacent blades 32 of the impeller 30. In the illustrated embodiment, the two endmost apertures are slightly longer than the other apertures.

During operation of the centrifugal blower 200, the impeller 30 rotates to generate forced airflow. Air in the ambient environment can be sucked into the space 24 not only through the first air inlet 221 and the second air inlet 25, but also through the opening 222 of the top plate 22. In the centrifugal blower 200, due to the presence of the opening 222, the amount of air sucked into the space 24 of the centrifugal blower 200 can be greatly increased. Thus the centrifugal blower 200 is capable of providing a large amount of airflow. Further, the opening 222 is spaced from the first air inlet 221 by the partition rib 223, thereby maintaining the profile of the first air inlet 221. Thus, noise produced by the centrifugal blower 200 is lower than that of a centrifugal blower with a side of an air inlet directly enlarged. Moreover, the connecting ribs 224 can firmly connect the partition rib 223 with the top plate 22 and allow the exterior air to evenly enter the space 24 to further reduce noise. The opening 222 of the top plate 22 can be easily formed during the process of manufacturing the top plate 22. Such a modification is quite simple, which facilitates easy manufacture of the centrifugal blower 200 and therefore decreases the cost of the centrifugal blower 200. Accordingly, the centrifugal blower 200 has an advantageously simple structure.

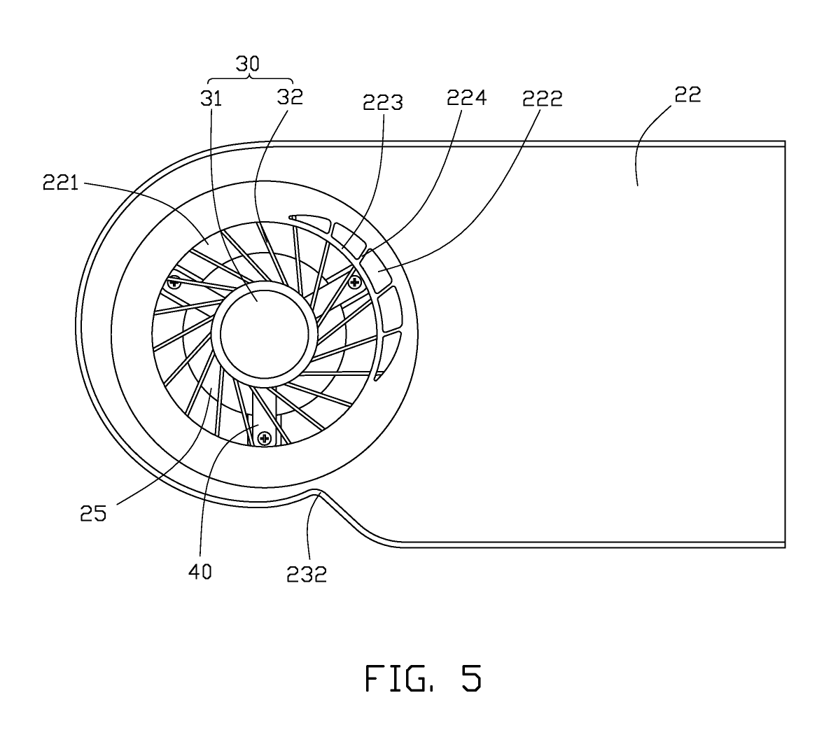

Operation of the conventional centrifugal blower 100 of FIG. 1 and the present centrifugal blower 200 of FIGS. 2-5 has been repeatedly simulated by using CFD software under different static pressures to measure the P-Q (static pressure-quantity of airflow) curves thereof. Table 1 below shows experimental data of the conventional centrifugal blower 100 and the present centrifugal blower 200. In Table 1, Q1 indicates the quantity of airflow of the centrifugal blower 100, and Q2 indicates the quantity of airflow of the centrifugal blower 200. When the static pressure is 20 Mpa (mega-pascals), the quantity of airflow generated by the present centrifugal blower 200 is 0.232 cfm (Cubic Feet Per Minute) (i.e., about 2.65%) more than that of the centrifugal blower 100 of FIG. 1. When the static pressure is 40 MPa, the quantity of airflow generated by the centrifugal blower 200 is 0.27 cfm, (i.e., about 3.6%) more than that of the centrifugal blower 100 of FIG. 1. When the static pressure is 60 MPa, the quantity of airflow generated by the centrifugal blower 200 is 0.45 cfm (i.e., about 7.76%) more than that of the centrifugal blower 100 of FIG. 1. When the static pressure is 80 MPa, the quantity of airflow generated by the centrifugal blower 200 is 0.747 cfm (i.e., about 22.9%) more than that of the centrifugal blower 100 of FIG. 1. As compared to the centrifugal blower 100 shown in FIG. 1, the performance of the centrifugal blower 200 is significantly increased, particularly when the centrifugal blower 200 runs at a high static pressure.

TABLE 1

| Pressure (MPa) | 20 | 40 | 60 | 80 |
|---|---|---|---|---|
| Q1 (cfm) | 8.73 | 7.5 | 5.798 | 3.253 |
| Q2 (cfm) | 8.962 | 7.77 | 6.248 | 4 |
| ΔQ (cfm) | 0.232 | 0.27 | 0.45 | 0.747 |
| Percentage | 2.65 | 3.6 | 7.76 | 22.9 |
| difference (%) | | | | |

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A centrifugal blower, comprising:
a housing defining a space therein, the housing comprising a bottom plate, an opposite top plate defining an air inlet therein, and a sidewall disposed between the bottom plate and the top plate, the sidewall defining an air outlet therein, the top plate further defining an opening therein between the air inlet and the air outlet, the opening being spaced from the air inlet via a partition rib; and
an impeller rotatably disposed in the space of the housing and located corresponding to the air inlet of the top plate, the impeller positioned for driving air to enter the housing via the air inlet and the opening and to leave the housing via the air outlet.

2. The centrifugal blower of claim 1, wherein the opening is elongated and extends along a periphery of the air inlet of the top plate.

3. The centrifugal blower of claim 2, wherein the opening is crescent-shaped.

4. The centrifugal blower of claim 3, wherein a plurality of connecting ribs are disposed in the opening and divide the opening into a plurality of spaced apertures.

5. The centrifugal blower of claim 4, wherein the connecting ribs are evenly arranged along a direction of extension of the crescent shape of the opening and are spaced from each other.

6. The centrifugal blower of claim 5, wherein the impeller comprises a hub and a plurality of blades extending radially and outwardly from the hub, a distance between two adjacent connecting ribs being substantially equal to a distance between two adjacent blades of the impeller.

7. The centrifugal blower of claim 1, wherein the sidewall has a tongue formed thereon at one side of the air outlet, the opening being located adjacent to the other side of the air outlet farthest from the tongue.

8. The centrifugal blower of claim 7, wherein the air inlet of the top plate is round-shaped in profile, the center of the air inlet being located on a rotation axis of the impeller.

9. The centrifugal blower of claim 8, wherein the bottom plate defines another air inlet therein corresponding to the impeller, the air inlet of the top plate being concentric with the air inlet of the bottom plate and having a diameter larger than that of the air inlet of the bottom plate.

10. A heat dissipation device, comprising:
a centrifugal blower, comprising:
a housing defining a space therein, the housing comprising a bottom plate, an opposite top plate defining an air inlet therein, and a sidewall disposed between the bottom plate and the top plate, the sidewall defining an air outlet therein, the top plate further defining an opening therein between the air inlet and the air outlet, the opening being spaced from the air inlet; and
an impeller rotatably disposed in the space of the housing and located corresponding to the air inlet of the top plate, the impeller positioned for driving air to enter the housing via the air inlet and the opening and to leave the housing via the air outlet; and
a plurality of fins disposed on the bottom plate and located at the air outlet of the centrifugal blower.

11. The heat dissipation device of claim 10, wherein the opening is elongated and extends along a periphery of the air inlet of the top plate.

12. The heat dissipation device of claim 11, wherein the opening is crescent-shaped.

13. The heat dissipation device of claim 11, wherein a plurality of connecting ribs are disposed in the opening, the connecting ribs connecting the partition rib with the top plate.

14. The heat dissipation device of claim 13, wherein the connecting ribs are evenly arranged along a direction of extension of the opening and are spaced from each other.

15. The heat dissipation device of claim 13, wherein the impeller comprises a hub and a plurality of blades extending radially and outwardly from the hub, a distance between two adjacent connecting ribs being substantially equal to a distance between two adjacent blades of the impeller.

16. The heat dissipation device of claim 10, wherein the sidewall forms a tongue thereon at one side of the air outlet, the opening being located adjacent to the other side of the air outlet farthest from the tongue.

17. The heat dissipation device of claim 16, wherein the air inlet of the top plate is round-shaped in profile, the center of the air inlet being located on a rotation axis of the impeller.

18. The heat dissipation device of claim 17, wherein the bottom plate defines another air inlet therein corresponding to the impeller, the air inlet of the top plate being concentric with the air inlet of the bottom plate and having a diameter larger than that of the air inlet of the bottom plate.

19. The heat dissipation device of claim 17, wherein the bottom plate has a heat absorbing block formed on an outer surface thereof corresponding to the fins.

20. The heat dissipation device of claim 10, wherein the top plate covers the fins.
